(19) United States
(12) Patent Application Publication
(10) Pub. No.: US 2009/0275182 A1
(43) Pub. Date: Nov. 5, 2009

(54) METHOD FOR FABRICATING A METAL HIGH DIELECTRIC CONSTANT TRANSISTOR WITH REVERSE-T GATE

(75) Inventors: LELAND CHANG, New York, NY (US); Isaac Lauer, White Plains, NY (US); Jeffrey W. Sleight, Ridgefield, CT (US)

Correspondence Address: FLEIT GIBBONS GUTMAN BONGINI & BIANCO P.L., 551 NW 77TH STREET, SUITE 111, BOCA RATON, FL, 33487, US

(73) Assignee: INTERNATIONAL BUSINESS MACHINES CORPORATION, ARMONK, NY (US)

(21) Appl. No.: 12/113,557

(22) Filed: May 1, 2008

(51) Int. Cl. H01L 21/336

(52) U.S. Cl. 438/287; 257/E21.433

(57) ABSTRACT

A method is provided for fabricating a transistor. A silicon layer is provided, and a first layer comprising a high dielectric constant material is formed on the silicon layer. A second layer including a metal or metal alloy is formed on the first layer, and a third layer including silicon or polysilicon is formed on the second layer. The first, second, and third layers are etched so as to form a gate stack, and ions are implanted to form source and drain regions in the silicon layer. Source and drain silicide contact areas are formed in the source and drain regions, and a gate silicide contact area is formed in the third layer. After forming these silicide contact areas, the third layer is etched without etching the first and second layers, so as to substantially reduce the width of the third layer.

### CROSS REFERENCE TO RELATED APPLICATIONS

This application is related to application “Transistor with High-K Dielectric Sidewall Spacer,” Ser. No. ______, now ______, and application “Metal High Dielectric Constant Transistor with Reverse-T Gate,” Ser. No. ______, now ______, which were filed on the same day as the present application and commonly assigned therewith to International Business Machines Corporation. These related applications are incorporated herein by reference in their entirety.

### FIELD OF THE INVENTION

The present invention generally relates to the field of semiconductors, and more particularly relates to metal high dielectric constant transistors.

### BACKGROUND OF THE INVENTION

Metal high dielectric constant (high-k) transistors, or “MHK transistors”, are experiencing extremely active development in the industry. One observed problem with such transistors relates to the presence of an elevated outer fringe capacitance Cof, on the order of 40-80 aF/μm. This elevated capacitance Cof occurs because the gate sidewall of an MHK transistor no longer depletes as in a transistor with a conventional polysilicon gate. The elevated value of outer fringe capacitance Cof is of concern because it at least impairs high frequency operation of the MHK transistor. The elevated value of this capacitance Cof has a performance impact of approximately 1.25% per 10 aF, resulting in a 5%-10% decrease in AC performance. Current technologies do not provide a reduction in the parasitic Miller capacitance when metal-like materials (such as TiN) are used.

### SUMMARY OF THE INVENTION

One embodiment of the present invention provides a method for fabricating a transistor. According to the method, a silicon layer is provided, and a first layer is formed on the silicon layer. A second layer is formed on the first layer, and a third layer is formed on the second layer. The first layer comprises a high dielectric constant material, the second layer includes a metal or metal alloy, and the third layer includes silicon or polysilicon. The first, second, and third layers are etched so as to form a gate stack, and ions are implanted so as to form source and drain regions in the silicon layer on opposite sides of the gate stack. A source silicide contact area is formed in the source region, a drain silicide contact area is formed in the drain region, and a gate silicide contact area is formed in the third layer of the gate stack. After forming the source, drain, and gate silicide contact areas, the third layer of the gate stack is etched without etching the first and second layers of the gate stack, so as to substantially reduce the width of the third layer of the gate stack.

Other objects, features, and advantages of the present invention will become apparent from the following detailed description. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIG. 1 is a cross-sectional view of a conventional metal high dielectric constant transistor;

FIG. 2 is a cross-sectional view of a metal high dielectric constant transistor having a reverse-T gate in accordance with one embodiment of the present invention; and

FIGS. 3-8 are cross-sectional views of a process for fabricating a metal high dielectric constant transistor having a reverse-T gate in accordance with an embodiment of the present invention.

### DETAILED DESCRIPTION

Embodiments of the present invention provide metal high dielectric constant (high-k) transistors (“MHK transistors”) with a reverse-T gate. The reverse-T gate includes a polysilicon layer with a substantially reduced width, which results in an increase in the distance between the polysilicon layer and the contact stud. Therefore, parasitic capacitance between the polysilicon gate layer and the contact stud is reduced.

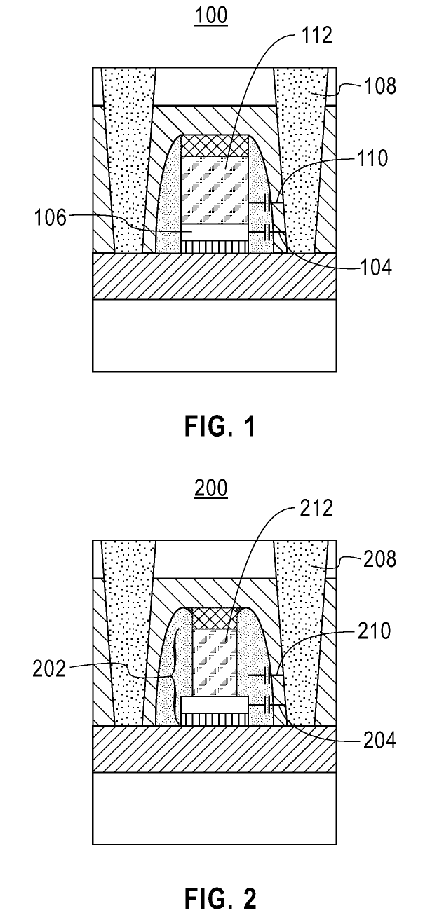

FIG. 1 shows a conventional MHK transistor, and FIG. 2 shows an MHK transistor having a reverse-T gate in accordance with one embodiment of the present invention. With respect to the conventional MHK transistor 100, a parasitic gate-to-contact capacitance is made up of a capacitance 104 between the metal gate layer 106 and the contact stud 108, and a capacitance 110 between the polysilicon gate layer 112 and the contact stud 108.

The MHK transistor 200 of FIG. 2 also has such a parasitic capacitance. However, in embodiments of the present invention, the polysilicon gate layer width is less than the width of the metal gate layer. For example, in this embodiment, the width of the polysilicon gate layer 212 is between about ⅓ and ½ of the width of the metal gate layer. Because the width of the polysilicon gate layer 212 is substantially reduced, the distance between the polysilicon gate layer 212 and the contact stud 208 is increased. Therefore, the capacitance between the polysilicon gate layer 212 and the contact stud 208 is reduced, which results in a parasitic gate-to-contact capacitance that is lower than in the conventional MHK transistor. As pitch scaling continues, this reduction in parasitic capacitance becomes more substantial.

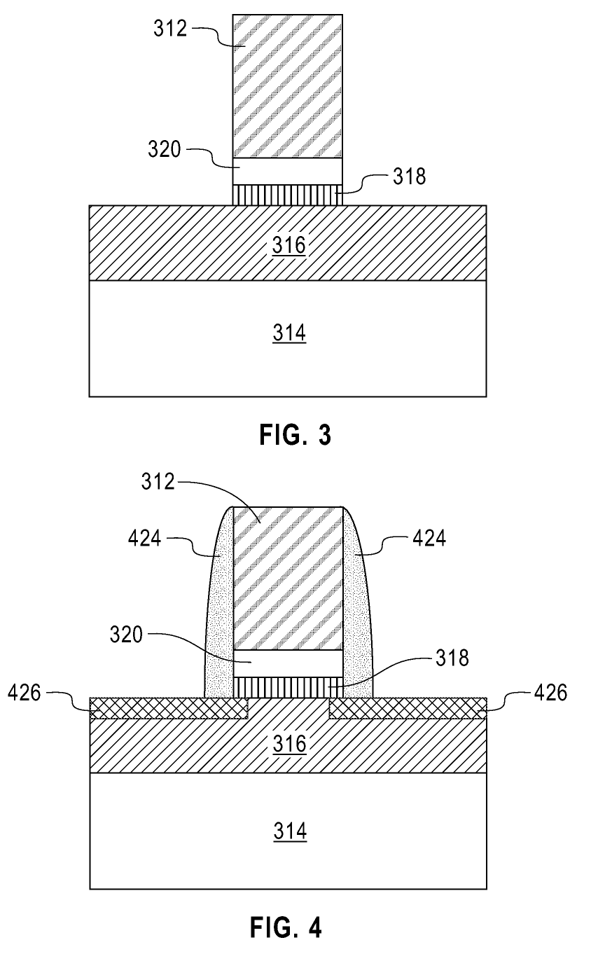

FIGS. 3-8 show one embodiment of a process for fabricating an MHK transistor with a reverse-T gate. The process begins with a silicon-on-insulator (SOI) wafer that has, formed on a silicon substrate, an overlying oxide layer (“BOX”) 314 (e.g., of 3 μm), and overlying silicon layer 316. A conventional high-k dielectric layer 318 and a metal layer 320 are deposited on the silicon layer 316. In this embodiment, the high-k layer 318 has an exemplary thickness in the range of about 1-3 nm, and comprises a material having a dielectric constant (k) in the range of about 20-25 (as compared to 3.9 for SiO₂), such as hafnium dioxide (HfO₂). The metal (or metal-like) layer 320 comprises a metal or metal alloy such as titanium nitride (TiN), and has a thickness of about 10 nm. These two layers 318 and 320 form the (as yet unpatterned) MHK gate stack layers. This initial structure represents a conventional SOI CMOS with an MHK gate stack. A polysilicon (or amorphous silicon) layer 312 is then deposited on top of the metal layer 320, with a thickness in the range of about 30-100 nm.

FIG. 3 shows the transistor formation process after a conventional gate stack etch has been performed (without showing the underlying silicon substrate for simplicity). In this embodiment, the gate stack etch stops at the silicon layer 316. After the gate stack is etched, a disposable spacer 424 is formed on sidewalls of the gate stack, as shown in FIG. 4.

The disposable spacer 424 of this embodiment is a nitride spacer that is formed by depositing a 5-50 nm thick nitride layer (e.g., using RTCVD or PECVD) and then performing a reactive ion etch (RIE) that stops on an underlying oxide liner so as not to consume any of the underlying silicon. Photolithography and ion implantation are then used to define source/drain extension. For an NFET the implant is performed using an n-type species, and for a PFET the implant is performed using a p-type species. Thus, source/drain extensions 426 are formed.

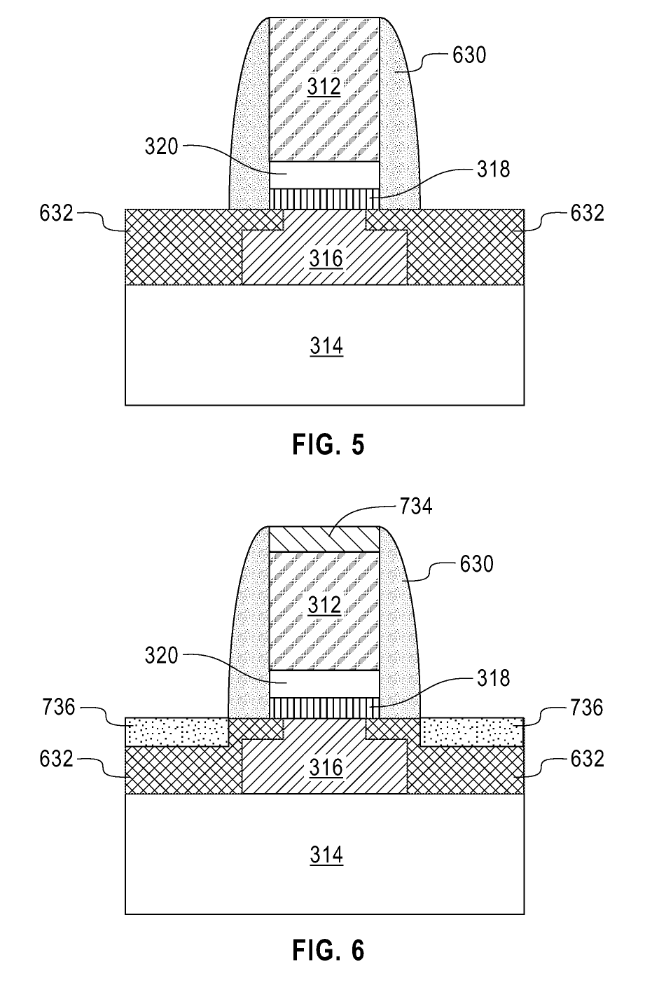

The disposable spacer 424 that was used to offset the ion implantation from the gate edge is then removed, such as through a hot phosphoric acid etch, other wet dip process, or through a highly selective RIE etch. As shown in FIG. 5, an oxide and/or nitride diffusion spacer 630 is formed by depositing and etching one or more layers of nitride and/or oxide (for example, using PECVD). The diffusion spacer 630 of this embodiment has an exemplary thickness of about 2-10 nm. Source and drain regions are then implanted. The source/drain implant is performed using a p-type species for an NFET (for example, As or P) or using an n-type species for a PFET (for example, B or BF₂). A subsequent rapid thermal anneal (RTA) is performed (e.g., millisecond laser anneal or flash anneal) to provide relatively deep diffusions for the source and drain regions 632, which are separated by the gate region.

Conventional processing is then used to silicide the gate, source, and drain (typically with Ni or Co) of the transistor, as shown in FIG. 6. The silicide contact areas 734 and 736 are formed using the diffusion spacer 630 for alignment. In particular, a portion for the contact area is removed (e.g., through a wet etch using HF), a metal is deposited, an anneal is performed to form silicide, and then the metal is selectively removed so as to leave the silicide (e.g., through an aqua regia wet etch). In this exemplary embodiment, the metal is nickel, cobalt, titanium, or platinum.

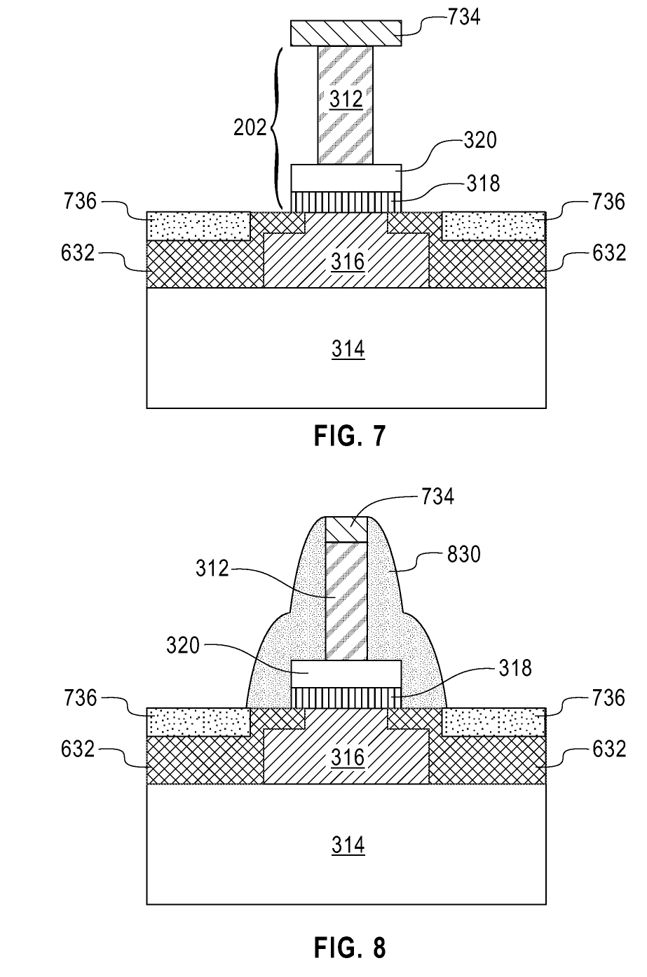

After the silicide contact areas 734 and 736 have been formed, the diffusion spacer 630 is removed, such as through RIE. This exposes the sides of the polysilicon layer 312 of the gate stack. The polysilicon layer 312 is then etched using a process that is selective between the polysilicon and the other exposed materials, such as a wet or dry etching. This etching substantially reduces the width of the polysilicon layer 312 of the gate stack. In this exemplary embodiment, the width of the polysilicon layer 312 is reduced to between about ⅓ and ½ of the width of the metal layer 320. This creates the “reverse-T gate 202, as shown in FIG. 7. That is, a lateral extent (width) of the high-k and metal layers 318 and 320 is substantially greater than a lateral extent (width) of the polysilicon layer 312 of the gate stack. As explained above, this substantial reduction in the width of the polysilicon layer 312 results in a reduction in the parasitic capacitance between the polysilicon layer and the adjacent contact stud.

Further, in this embodiment, this etch is selective with respect to the gate silicide contact area 734. Therefore, as shown in FIG. 7, the lateral extent (width) of the gate silicide contact area 734 is also substantially greater than the lateral extent (width) of the polysilicon layer 312 of the gate stack. In another embodiment, this etch is not selective with respect to the gate silicide contact area 734, so after etching the lateral extent (width) of the gate suicide contact area 734 is substantially equal to the lateral extent (width) of the polysilicon layer 312 of the gate stack.

Then, conventional fabrication processes are used to complete the transistor. For example, in this embodiment an oxide and/or nitride spacer 830 is formed by depositing and etching one or more layers of nitride and/or oxide (for example, using PECVD). As shown in FIG. 8, the spacer 830 of this embodiment has an exemplary thickness of about 2-10 nm.

Accordingly, the present invention provides metal high-k dielectric (MHK) transistors with a reverse-T gate. This reverse-T gate is a gate stack having a polysilicon layer with a substantially reduced width, which increases the distance between the polysilicon layer of the gate stack and the adjacent contact stud. Therefore, the parasitic capacitance between the polysilicon layer and the contact stud is reduced.

The embodiments of the present invention described above are meant to be illustrative of the principles of the present invention. These MHK device fabrication processes are compatible with CMOS semiconductor fabrication methodology, and thus various modifications and adaptations can be made by one of ordinary skill in the art. All such modifications still fall within the scope of the present invention.

For example, while the exemplary embodiments of the present invention described above relate to gate structures that use hafnium dioxide for the high-k layer and titanium nitride for the metal layer, further embodiments can use other compatible materials, such as ZrO₂ or HfSiₓO_{y}, which both exhibit the high dielectric constant (e.g., k of approximately 20-25) needed to provide a larger equivalent oxide thickness. Similarly, other metal oxide-based materials may be used, such as a uniform or a composite layer comprised of one or more of Ta₂O₅, TiO₂, Al₂O₃, Y₂O₃ and La₂O₅. The metal-containing layer 114 could also be formed of another material, such as one or more of Ta, TaN, TaCN, TaSiN, TaSi, AlN, W and Mo. Additionally, the upper layer 312 of the gate stack can be comprised of any material that is able to be etched, remain conductive, and withstand high temperatures. Similarly, while the embodiments described above relate to a transistor on an SOI wafer, the transistors and fabrication methods of the present invention are also applicable to bulk technologies. Likewise, the various layer thicknesses, material types, deposition techniques, and the like discussed above are not meant to be limiting.

Furthermore, some of the features of the examples of the present invention may be used to advantage without the corresponding use of other features. As such, the foregoing description should be considered as merely illustrative of the principles, teachings, examples and exemplary embodiments of the present invention, and not in limitation thereof.

It should be understood that these embodiments are only examples of the many advantageous uses of the innovative teachings herein. In general, statements made in the specification of the present application do not necessarily limit any of the various claimed inventions. Moreover, some statements may apply to some inventive features but not to others. In general, unless otherwise indicated, singular elements may be in the plural and vice versa with no loss of generality.

The circuit as described above is part of the design for an integrated circuit chip. The chip design is created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

The method as described above is used in the fabrication of integrated circuit chips.

The resulting integrated circuit chips can be distributed by the fabricator in raw wafer form (that is, as a single wafer that has multiple unpackaged chips), as a bare chip, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard, or other input device, and a central processor.

What is claimed is:

1. A method for fabricating a transistor, the method comprising the steps of:
providing a silicon layer;
forming a first layer on the silicon layer, the first layer comprising a high dielectric constant material;
forming a second layer on the first layer, the second layer comprising a metal or metal alloy;
forming a third layer on the second layer, the third layer comprising silicon or polysilicon;
etching the first, second, and third layers so as to form a gate stack;
implanting ions so as to form a source region and a drain region in the silicon layer on opposite sides of the gate stack;
forming a source silicide contact area in the source region, a drain silicide contact area in the drain region, and a gate silicide contact area in the third layer of the gate stack; and
after the step of forming the source, drain, and gate silicide contact areas, etching the third layer of the gate stack without etching the first and second layers of the gate stack, so as to substantially reduce the width of the third layer of the gate stack.

2. The method of claim 1, further comprising the step of:
before the step of implanting ions so as to form the source and drain regions, implanting ions so as to form source/drain extensions in the silicon layer.

3. The method of claim 1, further comprising the steps of:
after the step of implanting ions so as to form the source and drain regions and before the step of forming the source, drain, and gate silicide contact areas, depositing a spacer layer; and
etching the spacer layer so as to form a spacer on sidewalls of the gate stack,
wherein the step of forming the source, drain, and gate silicide contact areas comprises using the spacer to align the source and drain silicide contact areas, and removing the spacer after the source, drain, and gate silicide contact areas have been formed.

4. The method of claim 1, wherein after the step of etching the third layer of the gate stack, a lateral extent of the gate silicide contact area is substantially greater than a lateral extent of the third layer of the gate stack.

5. The method of claim 1, further comprising the step of:
after the step of etching the third layer of the gate stack, forming at least one spacer on sidewalls of the gate stack.

6. The method of claim 1, wherein the step of providing a silicon layer comprises:
providing a silicon substrate;
forming an oxide layer over the silicon substrate; and
forming the silicon layer over the oxide layer.

7. The method of claim 1, wherein the first layer of the gate stack comprises hafnium dioxide.

8. The method of claim 1, wherein the second layer of the gate stack comprises titanium or a titanium alloy.

9. A tangible computer readable medium encoded with a program for fabricating a transistor, the program comprising instructions for performing the steps of:
providing a silicon layer;
forming a first layer on the silicon layer, the first layer comprising a high dielectric constant material;
forming a second layer on the first layer, the second layer comprising a metal or metal alloy;
forming a third layer on the second layer, the third layer comprising silicon or polysilicon;
etching the first, second, and third layers so as to form a gate stack;
implanting ions so as to form a source region and a drain region in the silicon layer on opposite sides of the gate stack;
forming a source silicide contact area in the source region, a drain silicide contact area in the drain region, and a gate silicide contact area in the third layer of the gate stack; and
after the step of forming the source, drain, and gate silicide contact areas, etching the third layer of the gate stack without etching the first and second layers of the gate stack, so as to substantially reduce the width of the third layer of the gate stack.

10. The tangible computer readable medium of claim 9, wherein the program further comprises instructions for performing the step of:
before the step of implanting ions so as to form the source and drain regions, implanting ions so as to form source/drain extensions in the silicon layer.

11. The tangible computer readable medium of claim 9, wherein the program further comprises instructions for performing the steps of:
after the step of implanting ions so as to form the source and drain regions and before the step of forming the source, drain, and gate silicide contact areas, depositing a spacer layer; and
etching the spacer layer so as to form a spacer on sidewalls of the gate stack,
wherein the step of forming the source, drain, and gate silicide contact areas comprises using the spacer to align the source and drain silicide contact areas, and removing the spacer after the source, drain, and gate silicide contact areas have been formed.

12. The tangible computer readable medium of claim 9, wherein after the step of etching the third layer of the gate stack, a lateral extent of the gate silicide contact area is substantially greater than a lateral extent of the third layer of the gate stack.

13. The tangible computer readable medium of claim 9, wherein the program further comprises instructions for performing the step of:
after the step of etching the third layer of the gate stack, forming at least one spacer on sidewalls of the gate stack.

14. The tangible computer readable medium of claim 9, wherein the step of providing a silicon layer comprises:
providing a silicon substrate;
forming an oxide layer over the silicon substrate; and
forming the silicon layer over the oxide layer.

15. The tangible computer readable medium of claim 9, wherein the first layer of the gate stack comprises hafnium dioxide.

16. The tangible computer readable medium of claim 9, wherein the second layer of the gate stack comprises titanium or a titanium alloy.
